(19) United States
(12) Patent Application Publication
(10) Pub. No.: US 2025/0286561 A1
(43) Pub. Date: Sep. 11, 2025

(54) A/D Converter Circuit

(71) Applicant: SEIKO EPSON CORPORATION, Tokyo (JP)

(72) Inventor: Naohiro YASUDA, Chino (JP)

(21) Appl. No.: 19/074,801

(22) Filed: Mar. 10, 2025

(30) Foreign Application Priority Data
Mar. 11, 2024 (JP) 2024-036743

(51) Int. Cl. H03M 1/12; H03M 1/16

(52) U.S. Cl. CPC H03M 1/1245; H03M 1/164

(57) ABSTRACT

An A/D converter circuit includes a first pipeline stage outputting a first digital value of x bits by A/D conversion based on an input signal, a second pipeline stage outputting a second digital value of y bits smaller than the x bits by A/D conversion based on a first analog output signal of the first pipeline stage, and an A/D converter sampling a second analog output signal of the second pipeline stage in a sampling period shorter than a sampling period of the first pipeline stage and a sampling period of the second pipeline stage, performing A/D conversion based on a sampling result, and outputting a third digital value.

The present application is based on, and claims priority from JP Application Serial Number 2024-036743, filed Mar. 11, 2024, the disclosure of which is hereby incorporated by reference herein in its entirety.

### BACKGROUND

### 1. Technical Field

The present disclosure relates to an A/D converter circuit and the like.

### 2. Related Art

JP-A-2006-054608 discloses a pipeline A/D converter circuit including a 4-bit bit block and a 1.5-bit bit block sharing an amplifier. In JP-A-2006-054608, of the two bit blocks sharing the amplifier, the number of bits of the downstream stage is smaller than the number of bits of the upstream stage.

JP-A-2006-054608 is an example of the related art.

JP-A-2006-054608 does not disclose a configuration in which an A/D converter that operates at a clock faster than the clock of the pipeline A/D converter circuit is coupled to the downstream stage of the pipeline type A/D converter circuit. The publication does not disclose appropriate numbers of bits for the respective bit blocks.

### SUMMARY

An aspect of the present disclosure relates to an A/D converter circuit including a first pipeline stage outputting a first digital value of x bits by A/D conversion based on an input signal, a second pipeline stage outputting a second digital value of y bits smaller than the x bits by A/D conversion based on a first analog output signal of the first pipeline stage, and an A/D converter sampling a second analog output signal of the second pipeline stage in a sampling period shorter than a sampling period of the first pipeline stage and a sampling period of the second pipeline stage, performing A/D conversion based on a sampling result, and outputting a third digital value.

### BRIEF DESCRIPTION OF THE DRAWINGS

FIG. 1 shows a first configuration example of an A/D converter circuit.

FIG. 2 shows a timing chart example illustrating operations of pipeline stages and a cyclic A/D converter.

FIG. 3 shows a second configuration example of the A/D converter circuit.

FIG. 4 shows a timing chart example illustrating operations of pipeline stages and a successive approximation A/D converter.

FIG. 5 shows a detailed configuration example of the successive approximation A/D converter.

FIG. 6 shows a detailed configuration example of a first pipeline stage.

FIG. 7 shows a detailed configuration example of a capacitor circuit.

FIG. 8 shows an operation of the first pipeline stage.

FIG. 9 shows operations of an encoder and a switch group in a calculation and hold operation of a 2.5-bit pipeline stage.

FIG. 10 shows a detailed configuration example of a second pipeline stage.

FIG. 11 shows a detailed configuration example of a third pipeline stage.

FIG. 12 shows operations of the second and third pipeline stages.

FIG. 13 shows operations of an encoder and a switch group in a calculation and hold operation of a 1.5-bit pipeline stage.

FIG. 14 shows a detailed configuration example of a first stage of the cyclic A/D converter.

FIG. 15 shows a detailed configuration example of a second stage of the cyclic A/D converter.

FIG. 16 shows operations of the first stage and the second stage of the cyclic A/D converter.

FIG. 17 shows a timing chart example illustrating an overall operation of the A/D converter circuit.

FIG. 18 shows an operation of an adder.

### DESCRIPTION OF EMBODIMENTS

As below, preferred embodiments of the present disclosure will be described in detail. The following embodiments do not unduly limit the description in Claims, and not all of the configurations described in the embodiments are essential component elements.

### 1. A/D Converter Circuit

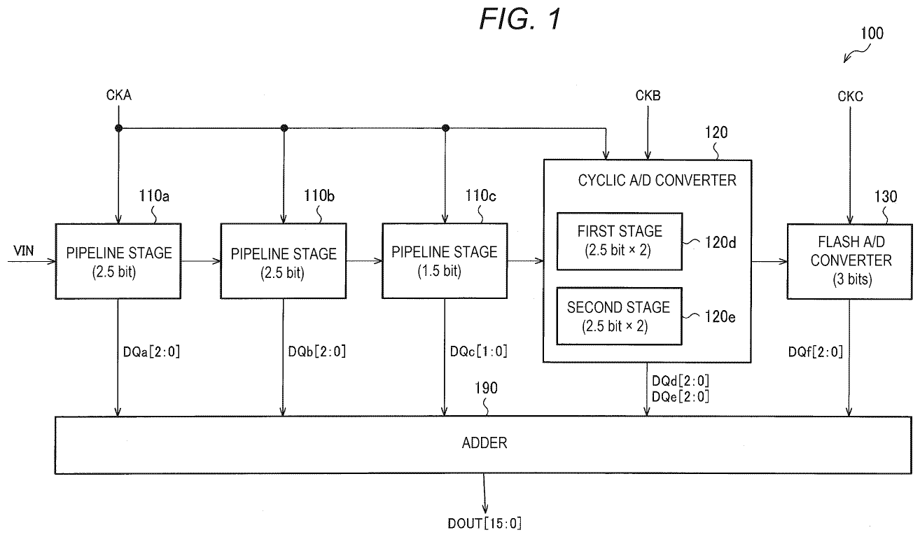

FIG. 1 shows a first configuration example of an A/D converter circuit. An A/D converter circuit 100 includes pipeline stages 110a, 110b, and 110c, a cyclic A/D converter 120, a flash A/D converter 130, and an adder 190.

The pipeline stage 110a samples an input voltage VIN to the A/D converter circuit 100, performs A/D conversion on the sampled voltage, and outputs the result of the A/D conversion as a digital value DQa [2:0]. The pipeline stage 110a multiplies the difference between the sampled voltage and the voltage obtained by D/A conversion of the digital value DQa [2:0] by a gain, and outputs the result. The digital value DQa [2:0] has a range of 2.5 bits. That is, the possible values of the digital value DQa [2:0] are seven values of 000b, 001b, 010b, 011b, 100b, 101b, and 110b. “b” at the end of the numerical value means the binary number.

The pipeline stage 110b samples the output voltage of the pipeline stage 110a, performs A/D conversion on the sampled voltage, and outputs the result of the A/D conversion as a digital value DQb [2:0]. The pipeline stage 110b multiplies the difference between the sampled voltage and the voltage obtained by D/A conversion of the digital value DQb [2:0] by a gain, and outputs the result. The digital value DQb [2:0] has a range of 2.5 bits.

The pipeline stage 110c samples the output voltage of the pipeline stage 110b, performs A/D conversion on the sampled voltage, and outputs the result of the A/D conversion as a digital value DQc [1:0]. The pipeline stage 110c multiplies the difference between the sampled voltage and the voltage obtained by D/A conversion of the digital value DQc [1:0] by a gain, and outputs the result. The digital value DQc [1:0] has a range of 1.5 bits smaller than the range of 2.5 bits of the digital value DQb [2:0] at the upstream stage. The possible values of the digital value DQc [1:0] are three values of 00b, 01b, and 10b.

The pipeline stages 110a, 110b, and 110c perform A/D conversion using a clock signal CKA as an operation clock signal. That is, the pipeline stages 110a, 110b, and 110c perform single A/D conversion for one cycle of the clock signal CKA.

In a first-cycle A/D conversion, the cyclic A/D converter 120 performs A/D conversion on the output voltage of the pipeline stage 110c and outputs the result as digital values DQd [2:0] and DQe [2:0]. In a second-cycle A/D conversion, the cyclic A/D converter 120 performs A/D conversion on the output voltage of the cyclic A/D converter 120 after the first-cycle A/D conversion, and outputs the result as digital values DQd [2:0] and DQe [2:0]. Each of the digital values DQd [2:0] and DQe [2:0] has a range of 2.5 bits. The two cycles of A/D conversion are performed, and thereby, data of 2.5 bits x 4 in total is obtained.

Specifically, the cyclic A/D converter 120 includes a first stage 120d and a second stage 120e.

The first-cycle A/D conversion is described. The first stage 120d samples the output voltage of the pipeline stage 110c, performs A/D conversion on the sampled voltage, and outputs the result of the A/D conversion as the digital value DQd [2:0]. The first stage 120d multiplies the difference between the sampled voltage and the voltage obtained by D/A conversion of the digital value DQd [2:0] by a gain, and outputs the result. The second stage 120e samples the output voltage of the first stage 120d, performs A/D conversion on the sampled voltage, and outputs the result of the A/D conversion as the digital value DQe [2:0]. The second stage 120e multiplies the difference between the sampled voltage and the voltage obtained by D/A conversion of the digital value DQe [2:0] by a gain, and outputs the result.

The second-cycle A/D conversion is described. The first stage 120d samples the output voltage of the second stage 120e after the first-cycle A/D conversion, performs A/D conversion on the sampled voltage, and outputs the result of the A/D conversion as the digital value DQd [2:0]. The subsequent operation is the same as that of the first-cycle A/D conversion.

The cyclic A/D converter 120 performs A/D conversion using clock signals CKA and CKB as operation clock signals. The cycle of the clock signal CKB is a half of the cycle of the clock signal CKA. The cyclic A/D converter 120 performs two A/D conversions based on the clock signal CKB for one cycle of the clock signal CKA.

The flash A/D converter 130 performs A/D conversion on the output voltage of the cyclic A/D converter 120 after the second-cycle A/D conversion, and outputs the result of the A/D conversion as a digital value DQf [2:0]. The flash A/D converter 130 includes a reference voltage generation circuit and a plurality of comparators. The reference voltage generation circuit generates a plurality of reference voltages and inputs one reference voltage to each comparator. The comparator compares the input voltage to the flash A/D converter 130 with the reference voltage input to the comparator. The flash A/D converter 130 outputs the digital value DQf [2:0] based on the output of the plurality of comparators.

The flash A/D converter 130 operates using a clock signal CKC as an operation clock. The cycle of the clock signal CKC is the same as the cycle of the clock signal CKA, but the phase of the clock signal CKC is different from the phase of the clock signal CKA. Specifically, the sampling timing of the flash A/D converter 130 with the clock signal CKC is shifted by a half cycle from the sampling timing of the pipeline stage 110a with the clock signal CKA.

The adder 190 outputs an output digital value DOUT [15:0] of the A/D converter circuit 100 by adding the digital values DQa [2:0], DQb [2:0], and DQc [1:0], the first-cycle DQd [2:0], the first-cycle DQe [2:0], the second-cycle DQd [2:0], the second-cycle DQe [2:0], and DQf [2:0].

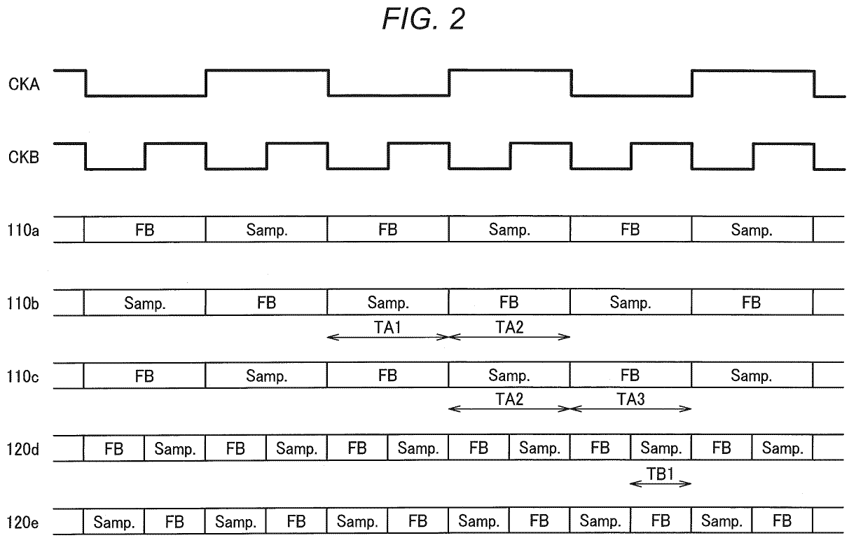

FIG. 2 shows a timing chart example illustrating operations of the pipeline stages and the cyclic A/D converter. The phases of the clock signals CKA and CKB are synchronized at a trailing edge. “Samp”. refers to a sampling operation and “FB” refers to a calculation and hold operation. The calculation and hold operation refers to an operation in which a D/A converter provided in the pipeline stage performs D/A conversion on a digital value and calculates a difference between the sampled voltage and the D/A conversion result.

The pipeline stages 110a and 110c perform sampling operations in a period in which the clock signal CKA is at a high level, and perform calculation and hold operations in a period in which the clock signal CKA is at a low level. The pipeline stage 110b performs a sampling operation in the period in which the clock signal CKA is at the low level, and performs a calculation and hold operation in the period in which the clock signal CKA is at the high level.

The cyclic A/D converter 120 starts the first-cycle A/D conversion in a period in which the pipeline stage 110c calculates and holds, and starts the second-cycle A/D conversion in a period in which the pipeline stage 110c performs the sampling operation.

The first stage 120d of the cyclic A/D converter 120 performs a sampling operation in a period in which the clock signal CKB is at a high level, and performs a calculation and hold operation in a period in which the clock signal CKB is at a low level. The second stage 120e performs a sampling operation in a period in which the clock signal CKB is at the low level, and performs a calculation and hold operation in a period in which the clock signal CKB is at the high level.

Hereinafter, the pipeline stage 110b two stages before the cyclic A/D converter 120 is referred to as a first pipeline stage, and the pipeline stage 110c one stage before the cyclic A/D converter 120 is referred to as a second pipeline stage. As described in FIG. 1, the first pipeline stage 110b outputs the digital value DQb [2:0] of 2.5 bits, and the second pipeline stage 110c outputs the digital value DQc [1:0] of 1.5 bits smaller than 2.5 bits. Thereby, the first stage 120d of the cyclic A/D converter 120 can accurately sample the output voltage of the second pipeline stage 110c. This point will be described with reference to FIG. 2 etc.

As shown in FIG. 2, the first pipeline stage 110b performs the sampling operation in a first period TA1. In a second period TA2 after the first period TA1, the first pipeline stage 110b performs the calculation and hold operation, and the second pipeline stage 110c performs the sampling operation. In a third period TA3 after the second period TA2, the second pipeline stage 110c performs the calculation and hold operation. Further, in the third period TA3, the first stage 120d of the cyclic A/D converter 120 performs the sampling operation. More specifically, a sampling period TB1 of the first stage 120d corresponds to a second half period of the third period TA3 divided into two by the clock signal CKB. The sampling period TB1 of the first stage 120d is shorter than the first period TA1 as a sampling period of the first pipeline stage 110b and the second period TA2 as a sampling period of the second pipeline stage 110c.

For accurate sampling by the first stage 120d, it is necessary that the output voltage of the second pipeline stage 110c is sufficiently settled before the end of the sampling period TB1 at which the sampled voltage of the first stage 120d is fixed. According to the embodiment, since the number of bits of the second pipeline stage 110c is smaller, the accuracy of the settling is higher.

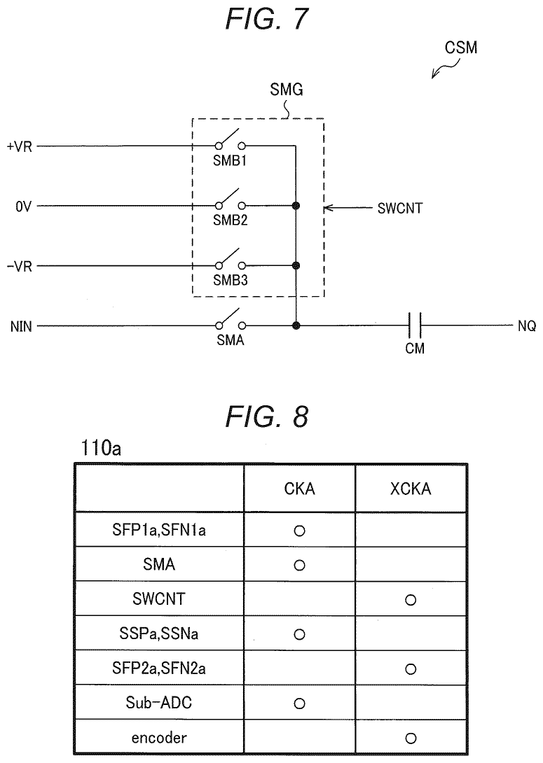

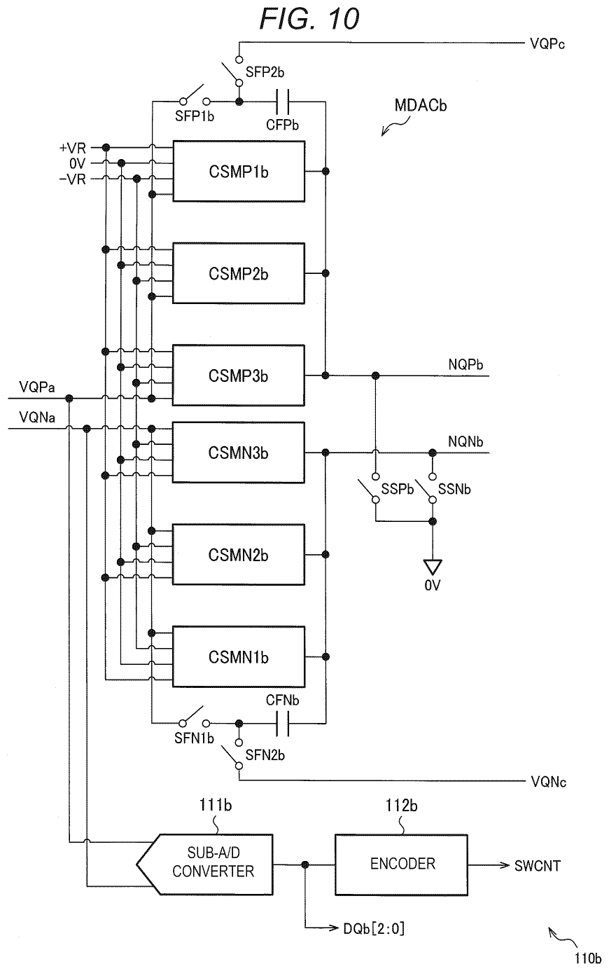

Specifically, as will be described later with reference to FIG. 10, the first pipeline stage 110b includes a D/A converter MDACb that performs D/A conversion by switching of the capacitor. The D/A converter MDACb includes three positive and negative capacitor circuits CSMP1b to CSMP3b and CSMN1b to CSMN3b corresponding to 2.5 bits. Each of the capacitor circuits includes a capacitor CM shown in FIG. 7.

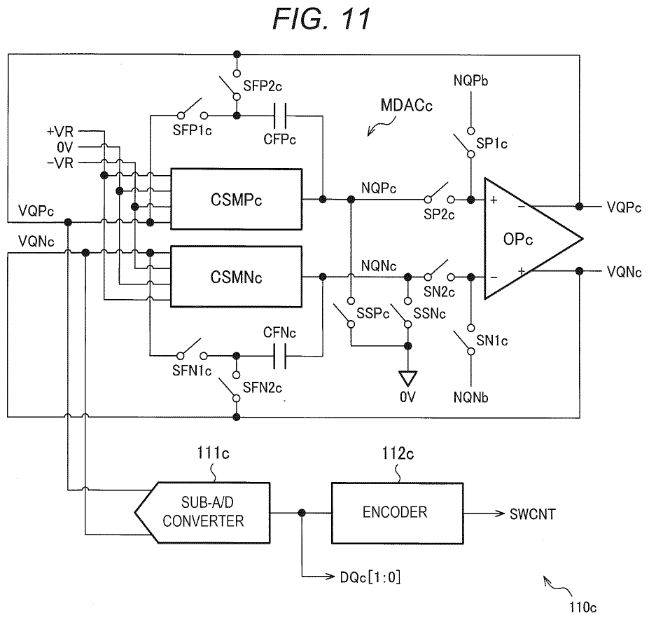

Further, as will be described later with reference to FIG. 11, the second pipeline stage 110c includes a D/A converter MDACc that performs D/A conversion by switching of the capacitor. The D/A converter MDACc includes one positive and negative capacitor circuits CSMPc and CSMNc corresponding to 1.5 bits. Each of the capacitor circuits includes the capacitor CM shown in FIG. 7.

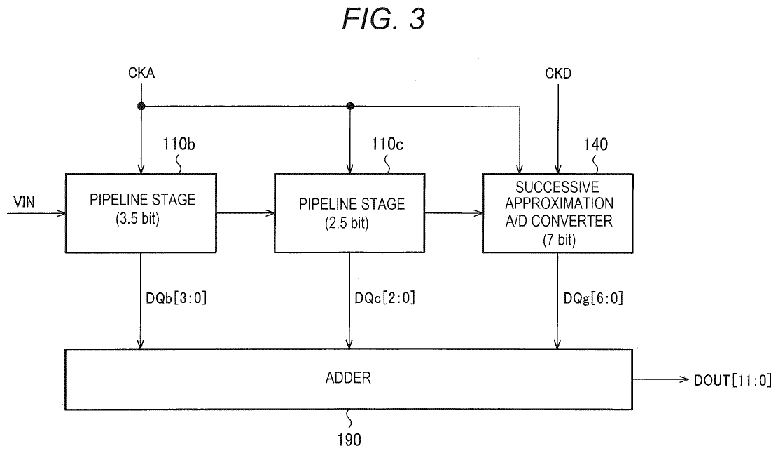

Each capacitor circuit is a load on the feedback path of the D/A converter in the calculation and hold operation. The larger the number of bits of the pipeline stage, the larger the number of capacitor circuits and the larger the load of the feedback path. Therefore, the larger the number of bits of the pipeline stage, the lower the settling accuracy. According to the embodiment, since the second pipeline stage 110c upstream of the cyclic A/D converter 120 has the small number of bits, the settling accuracy is higher and, even in the shorter sampling period TB1, the first stage 120d can accurately perform sampling. FIG. 3 shows a second configuration example of the A/D converter circuit. The A/D converter circuit 100 includes a first pipeline stage 110b, a second pipeline stage 110c, a successive approximation A/D converter 140, and an adder 190.

The first pipeline stage 110b samples an input voltage VIN to the A/D converter circuit 100, performs A/D conversion on the sampled voltage, and outputs the result of the A/D conversion as a digital value DQb [3:0]. The first pipeline stage 110b multiplies the difference between the sampled voltage and the voltage obtained by D/A conversion of the digital value DQb [3:0] by a gain, and outputs the result. The digital value DQb [3:0] has a range of 3.5 bits. That is, the possible values of the digital value DQb [3:0] are 15 values of 0000b, 0001b, 0010b, 1100b, 1101b, and 1110b.

The second pipeline stage 110c samples the output voltage of the first pipeline stage 110b, performs A/D conversion on the sampled voltage, and outputs the result of the A/D conversion as a digital value DQc [2:0]. The second pipeline stage 110c multiplies the difference between the sampled voltage and the voltage obtained by D/A conversion of the digital value DQc [2:0] by a gain, and outputs the result. The digital value DQc [2:0] has a range of 2.5 bits smaller than the range of 3.5 bits of the digital value DQb [3:0] of the upstream stage.

The first pipeline stage 110b and the second pipeline stage 110c perform A/D conversion using a clock signal CKA as an operation clock signal. That is, the first pipeline stage 110b and the second pipeline stage 110c perform one A/D conversion for one cycle of the clock signal CKA.

The successive approximation A/D converter 140 samples the output voltage of the second pipeline stage 110c, performs A/D conversion on the sampled voltage by successive approximation with respect to the sampled voltage, and outputs the result of the A/D conversion as a digital value DQg [6:0].

The successive approximation A/D converter 140 operates using a clock signal CKD as an operation clock. The successive approximation A/D converter 140 performs one A/D conversion by successive approximation based on the clock signal CKD for one cycle of the clock signal CKA. The frequency of the clock signal CKD is higher than the frequency of the clock signal CKA so that successive approximation of the number of bits of the successive approximation A/D converter 140 can be performed.

The adder 190 adds the digital values DQb [3:0], DQc [2:0], and Dog [6:0] and outputs an output digital value DOUT [11:0] of the A/D converter circuit 100.

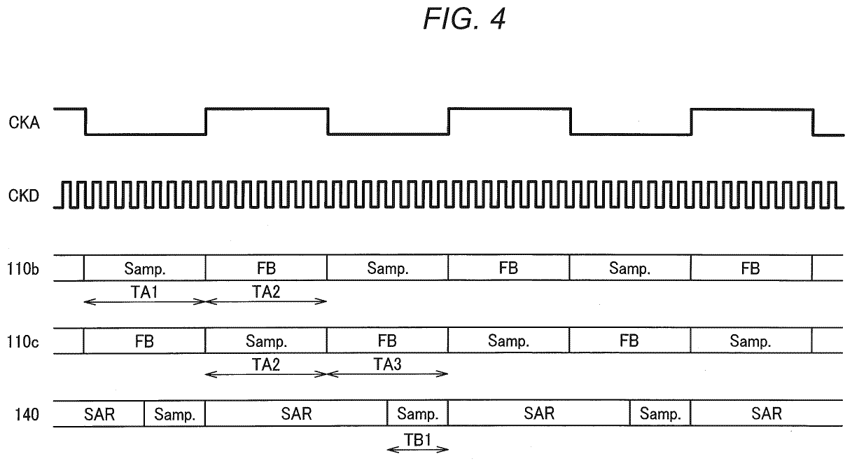

FIG. 4 shows a timing chart example illustrating operations of the pipeline stages and the successive approximation A/D converter. Here, it is assumed that the frequency of the clock signal CKD is 16 times the frequency of the clock signal CKA. “Samp”. refers to a sampling operation, “FB” refers to a calculation and hold operation, and “SAR” refers to successive approximation.

The first pipeline stage 110b performs a sampling operation in a period in which the clock signal CKA is at a low level, and performs a calculation and hold operation in a period in which the clock signal CKA is at a high level. The second pipeline stage 110c performs a sampling operation in a period in which the clock signal CKA is at the high level, and performs a calculation and hold operation in a period in which the clock signal CKA is at the low level.

The successive approximation A/D converter 140 starts a sampling operation during the period in which the second pipeline stage 110c calculates and holds, and performs successive approximation after the end of the sampling operation. For example, the sampling operation is performed in a period corresponding to a plurality of clocks of the clock signal CKD. In the example of FIG. 4, the period in which the second pipeline stage 110c calculates and holds corresponds to eight clocks of the clock signal CKD. FIG. 4 shows an example in which the sampling operation is performed in a period corresponding to the last four clocks of the eight clocks. The successive approximation is performed on one bit for one clock of the clock signal CKA from the MSB side of the digital value DQg [6:0].

As described in FIG. 3, the first pipeline stage 110b outputs the digital value DQb [3:0] of 3.5 bits, and the second pipeline stage 110c outputs the digital value DQc [2:0] of 2.5 bits smaller than 3.5 bits. Thereby, the successive approximation A/D converter 140 can accurately sample the output voltage of the second pipeline stage 110c. This is on the same reason as the reason described with reference to FIG. 2 of the first configuration example.

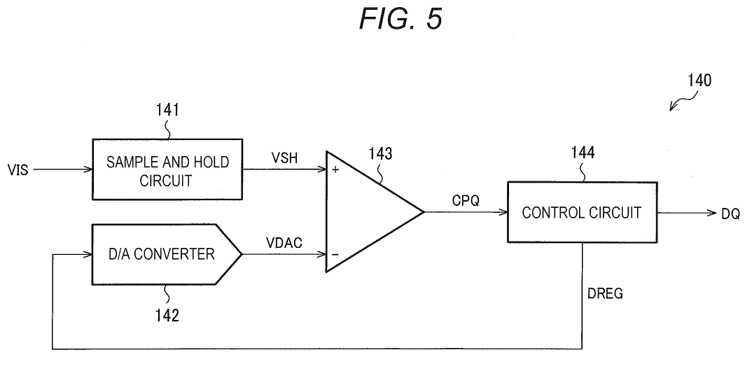

FIG. 5 shows a detailed configuration example of the successive approximation A/D converter. The successive approximation A/D converter 140 includes a sample and hold circuit 141, a D/A converter 142, a comparator 143, and a control circuit 144.

The sample and hold circuit 141 samples and holds a voltage VIS input to the successive approximation A/D converter 140 and outputs a held voltage VSH. The voltage VIS corresponds to the output voltage of the second pipeline stage 110c in FIG. 3. The D/A converter 142 performs D/A conversion on a successive approximation register value DREG from the control circuit 144, and outputs the result of the D/A conversion as a voltage VDAC. The comparator 143 compares the voltage VSH with the voltage VDAC, and outputs the comparison result as a signal CPQ. The control circuit 144 updates the successive approximation register value DREG based on the signal CPQ, and outputs the updated successive approximation register value DREG to the D/A converter 142. The control circuit 144 sequentially determines the successive approximation register value DREG from the MSB side to the LSB one bit at a time, and outputs the successive approximation register value DREG determined up to the LSB as a digital value DQ. The digital value DQ corresponds to the digital value DQg [6:0] in FIG. 3.

Note that the configuration of the successive approximation A/D converter 140 is not limited to that in FIG. 5. For example, the D/A converter 142 may be a capacitor DAC and include the function of the sample and hold circuit 141. In this case, the capacitor DAC may sample and hold the voltage VIN and output the difference between the held voltage and a voltage obtained by D/A conversion of the successive approximation register value DREG. The comparator may compare the output voltage of the capacitor DAC with the reference voltage.

In the embodiment, the A/D converter circuit 100 includes a first pipeline stage 110b, a second pipeline stage 110c, and an A/D converter. The first pipeline stage 110b outputs a first digital value of x bits by A/D conversion based on an input signal. The second pipeline stage 110c outputs a second digital value of y bits smaller than x bits by A/D conversion based on a first analog output signal of the first pipeline stage 110b. The A/D converter samples a second analog output signal of the second pipeline stage 110c in a sampling period shorter than the sampling period of the first pipeline stage 110b and the sampling period of the second pipeline stage 110c, performs A/D conversion based on the sampling result, and outputs a third digital value.

According to the embodiment, the second pipeline stage 110c outputs the second digital value of the y bits smaller than the x bits of the first digital value output by the first pipeline stage 110b. Thereby, the load of the feedback path when the second pipeline stage 110c performs the calculation and hold operation becomes smaller, and the second pipeline stage 110c can settle the sampled voltage of the downstream A/D converter faster. Accordingly, even when the A/D converter downstream of the second pipeline stage 110c performs sampling in a shorter sampling period, accurate sampling can be performed.

In the examples of FIGS. 1 and 3, “input signal” corresponds to a signal of the input voltage VIN. “First analog output signal” corresponds to a signal of the output voltage of the first pipeline stage 110b, and “second analog output signal” corresponds to a signal of the output voltage of the second pipeline stage 110c. “First digital value” corresponds to the digital value DQb [2:0], and “second digital value” corresponds to the digital value DQc [1:0]. In the example of FIG. 1, “A/D converter” corresponds to the cyclic A/D converter 120, and “third digital value” corresponds to the digital value Dod [2:0] and DQe [2:0]. In the example of FIG. 3, “A/D converter” corresponds to the successive approximation A/D converter 140, and “third digital value” corresponds to the digital value DQg [6:0].

Further, in the embodiment, the first pipeline stage 110b may perform a sampling operation in the first period TA1. In the second period TA2 after the first period TA1, the first pipeline stage 110b may perform a calculation and hold operation, and the second pipeline stage 110c may perform a sampling operation. In the third period TA3 after the second period TA2, the second pipeline stage 110c may perform a calculation and hold operation, and the A/D converter may perform a sampling operation.

According to the embodiment, in the second period, the second pipeline stage 110c can sample the first analog output signal output by the first pipeline stage 110b performing the calculation and hold operation. In the third period, the A/D converter can sample the second analog output signal output by the second pipeline stage 110c performing the calculation and hold operation. As described above, the sampling period of the A/D converter is shorter, however, the number of bits of the second pipeline stage 110c is smaller and the accurate sampling can be performed.

As described with reference to FIG. 1, the A/D converter may be the cyclic A/D converter 120. In the embodiment, the cyclic A/D converter 120 may perform a first-cycle A/D conversion of A/D-converting the second analog output signal in a period in which the first pipeline stage 110b and the second pipeline stage 110c perform single A/D conversion, and perform a second-cycle A/D conversion of A/D-converting an analog output signal output by the cyclic A/D converter again after the first-cycle A/D conversion.

According to the embodiment, the cyclic A/D converter 120 performs a plurality of cyclic A/D conversions in a period in which the pipeline stage performs one A/D conversion. As described above, since the A/D conversion rate of the cyclic A/D converter 120 is higher than the A/D conversion rate of the pipeline stage, the sampling period of the cyclic A/D converter 120 is shorter than the sampling period of the pipeline stage. According to the embodiment, even in the case, the cyclic A/D converter 120 can accurately perform sampling.

Further, as described in FIG. 3, the A/D converter may be the successive approximation A/D converter 140. In the embodiment, the successive approximation A/D converter 140 may perform a sampling operation of sampling the second analog output signal and a successive approximation operation on the sampled second analog output signal in a period in which the first pipeline stage 110b and the second pipeline stage 110c perform single A/D conversion.

The successive approximation A/D converter 140 performs successive approximation one bit at a time, and thus the sampling period is likely to be shorter to secure the period of the successive approximation operation. According to the embodiment, even when the sampling period of the successive approximation A/D converter 140 is shorter, the successive approximation A/D converter 140 can accurately perform sampling.

Further, in the embodiment, the x bits may be n+0.5 bits. n is an integer of one or more. The y bit may be m+0.5 bits. m is an integer of one or more and less than n.

According to the embodiment, the first pipeline stage 110b performs A/D conversion of n+0.5 bits. Then, the second pipeline stage 110c upstream of the A/D converter performs A/D conversion of m+0.5 bits smaller than n+0.5 bits. This improves the sampling accuracy of the A/D converter as described above.

In the embodiment, the third digital value may be of z bits larger than the x bits and the y bits.

According to the embodiment, the A/D converter performs A/D conversion of the number of bits larger than the numbers of bits of the first pipeline stage 110b and the second pipeline stage 110c.

In the embodiment, the A/D converter circuit 100 may include a flash A/D converter 130 provided downstream of the A/D converter.

According to the embodiment, the flash A/D converter 130 is provided downstream, and thereby, the conversion speed can be secured and the number of conversion bits in the entire A/D converter circuit 100 can be increased. The conversion accuracy at the MSB side can be secured by the upstream pipeline stage, and the conversion speed at the LSB side can be improved by the downstream flash A/D converter 130.

In the embodiment, the A/D converter circuit 100 may include an adder 190. The adder 190 may output an output digital value of the A/D converter circuit 100 based on the first digital value, the second digital value, and the third digital value.

According to the embodiment, the output digital value of the A/D converter circuit 100 can be calculated from the digital values output by the first pipeline stage 110b, the second pipeline stage 110c, and the A/D converter. Note that “output digital value” corresponds to the output digital value DOUT [15:0] in FIG. 1 or the output digital value DOUT [11:0] in FIG. 3.

2. Detailed Configuration Examples of Pipeline Stages, Cyclic A/D converter, and Adder

The detailed configuration examples of the pipeline stages 110a to 110c, the cyclic A/D converter 120, and the adder 190 of FIG. 1 will be described.

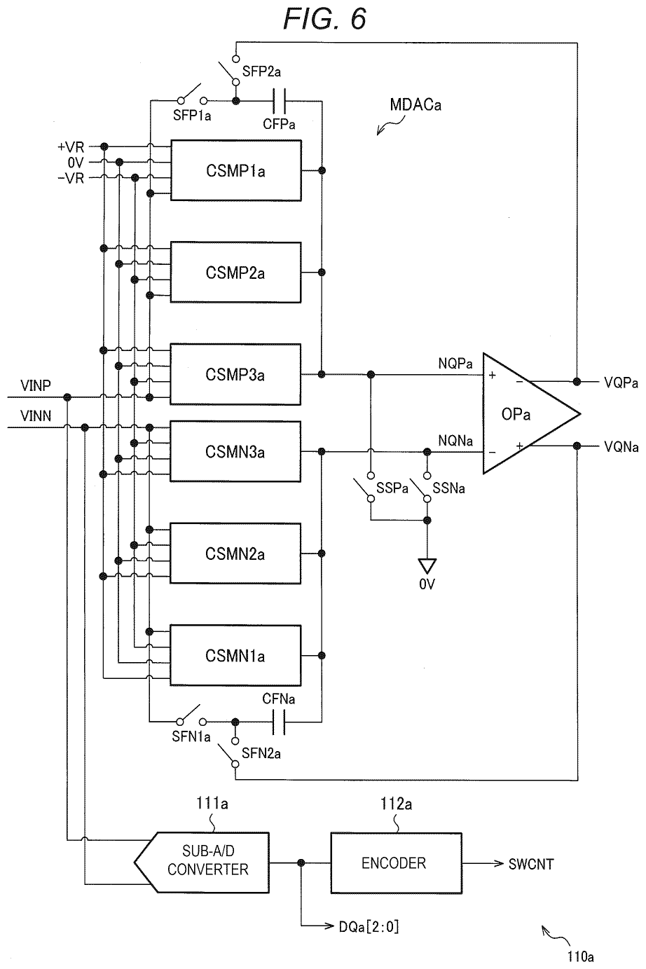

FIG. 6 shows a detailed configuration example of the first pipeline stage. The pipeline stage 110a includes a D/A converter MDACa, a sub-A/D converter 111a, and an encoder 112a.

A positive input voltage VINP and a negative input voltage VINN are input to the pipeline stage 110a. The difference between the input voltages VINP and VINN corresponds to the input voltage VIN of the A/D converter circuit 100 in FIG. 1.

The sub-A/D converter 111a performs A/D conversion on the differential voltage (VINP−VINN) by the comparison using a reference voltage VR, and outputs the result of the A/D conversion as the digital value DQa [2:0]. +VR to −VR corresponds to the full scale of the differential voltage (VINP−VINN). The sub-A/D converter 111a performs A/D conversion as in the following expression (1). The differential voltage (VINP−VINN) is denoted by VIN.

$$- V R \leq V IN \leq - 5 / 8 \times V R : DQa [ 2 : 0 ] = 000 b , \qquad ( 1 )$$

$$- 5 / 8 \times V R < V IN \leq - 3 / 8 \times V R : DQa [ 2 : 0 ] = 001 b ,$$

$$- 3 / 8 \times V R < V IN \leq - 1 / 8 \times V R : DQa [ 2 : 0 ] = 010 b ,$$

$$- 1 / 8 \times V R < V IN \leq + 1 / 8 \times V R : DQa [ 2 : 0 ] = 011 b ,$$

$$+ 1 / 8 \times V R < V IN \leq + 3 / 8 \times V R : DQa [ 2 : 0 ] = 100 b ,$$

$$+ 3 / 8 \times V R < V IN \leq + 5 / 8 \times V R : DQa [ 2 : 0 ] = 101 b ,$$

$$+ 5 / 8 \times V R < V IN \leq + V R : DQa [ 2 : 0 ] = 110 b$$

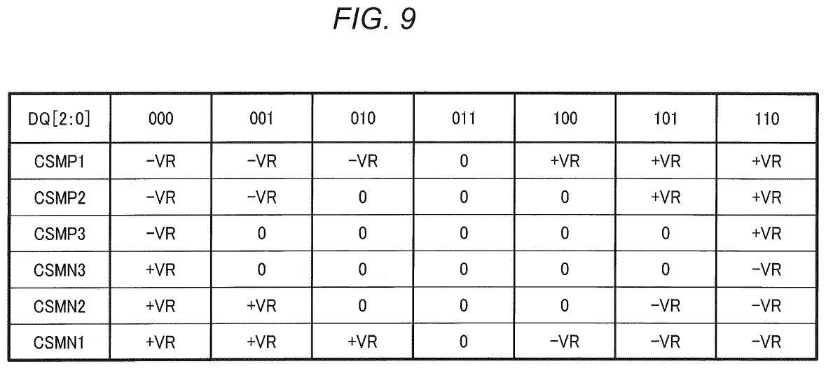

The encoder 112a encodes the digital value DQa [2:0] to a control signal SWCNT. The control signal SWCNT is a signal for controlling a switch group SMG, which will be described later with reference to FIG. 7. The control of switches SMB1 to SMB3 will be described later with reference to FIG. 9.

The D/A converter MDACa includes capacitor circuits CSMP1a, CSMP2a, and CSMP3a at the positive side, and capacitor circuits CSMN1a, CSMN2a, and CSMN3a at the negative side. Further, the D/A converter MDACa includes switches SFP1a, SFP2a, SFN2a, SEN1a, SSPa, and SSNa, capacitors CFPa and CFNa, and an operational amplifier OPa.

The capacitor circuits CSMP1a, CSMP2a, and CSMP3a are provided in parallel between a node of the input voltage VINP and a node NQPa coupled to the positive input terminal of the operational amplifier OPa. The switch SFP1a and the capacitor CFPa are coupled in series between the node of the input voltage VINP and the node NQPa. The switch SFP2a is coupled between a node between the switch SFP1a and the capacitor CFPa and a node of a positive output voltage VQPa. The switch SSPa is coupled between the node NQPa and the ground node. The negative output terminal of the operational amplifier OPa is coupled to the node of the positive output voltage VQPa. The D/A converter MDACa is a forward amplifier circuit for VIN, and the output voltage VQPa is defined as a positive voltage.

The capacitor circuits CSMN1a, CSMN2a, and CSMN3a are provided in parallel between a node of the input voltage VINN and a node NQNa coupled to the negative input terminal of the operational amplifier OPa. The switch SFN1a and the capacitor CFNa are coupled in series between the node of the input voltage VINN and the node NQNa. The switch SFN2a is coupled between a node between the switch SFN1a and the capacitor CFNa and a node of a negative output voltage VQNa. The switch SSNa is coupled between the node NQNa and the ground node. The positive output terminal of the operational amplifier OPa is coupled to the node of the negative output voltage VQNa.

FIG. 7 shows a detailed configuration example of the capacitor circuit. A capacitor circuit CSM shown in FIG. 7 corresponds to each of the capacitor circuits CSMP1a, CSMP2a, CSMP3a, CSMN1a, CSMN2a, and CSMN3a in FIG. 6. The capacitor circuit CSM includes the capacitor CM, a switch SMA, and the switch group SMG. The switch group SMG includes the switches SMB1, SMB2, and SMB3.

One end of the switch SMA is coupled to a node NIN, and the other end is coupled to a node N1. One end of the capacitor CM is coupled to the node N1, and the other end is coupled to a node NQ. In correspondence with FIG. 6, the node NIN is the node of the input voltage VINP, and the node NQ is the node NQPa. Alternatively, the node NIN is the node of the input voltage VINN, and the node NQ is the node NQNa.

One end of the switch SMB1 is coupled to a node of a positive reference voltage +VR, and the other end is coupled to the node N1. One end of the switch SMB2 is coupled to a node of 0V as the ground voltage, and the other end is coupled to the node N1. One end of the switch SMB3 is coupled to a node of a negative reference voltage-VR, and the other end is coupled to the node N1. Each of the switches SMB1, SMB2, and SMB3 is controlled to be on or off by the control signal SWCNT.

FIG. 8 shows an operation of the first pipeline stage. XCKA is a logically inverted signal of the clock signal CKA. A circle indicates whether each element operates in response to the clock signal CKA or the clock signal XCKA.

When the clock signal CKA is at the high level, the pipeline stage 110a performs the sampling operation. Specifically, the switches SFP1a, SFN1a, SMA, SSPa, and SSNa are on. All of the switches SMB1, SMB2, and SMB3 of the switch group SMG are off. The switches SFP2a and SFN2a are off. Accordingly, the input voltage VINP is sampled in the capacitors CM of the capacitor circuits CSMP1a, CSMP2a, and CSMP3a and the capacitor CFPa. The input voltage VINN is sampled in the capacitors CM of the capacitor circuits CSMN1a, CSMN2a, and CSMN3a and the capacitor CFNa.

When the clock signal CKA is at the low level, the pipeline stage 110a performs the calculation and hold operation. Specifically, the switches SFP1a, SFN1a, SMA, SSPa, and SSNa are off. The encoder 112a encodes the digital value DQa [2:0] and outputs the control signal SWCNT, and each of the switches SMB1, SMB2, and SMB3 of the switch group SMG is controlled by the control signal SWCNT. The switches SFP2a and SFN2a are on. Thereby, a feedback path of the operational amplifier OPa is formed via the capacitors CFPa and CFNa.

FIG. 9 shows operations of an encoder and a switch group in a calculation and hold operation of a 2.5-bit pipeline stage. In FIG. 9, the column of “DQ [2:0]” indicates the respective values of the digital value DQa [2:0]. The row of “CSMP1” indicates the operation of the switch group SMG of the capacitor circuit CSMP1a in the respective values of the digital value DQa [2:0]. The same applies to the rows of “CSMP2”, “CSMP3”, “CSMN1”, “CSMN2”, and “CSMN3”. “+VR” indicates that the switch SMB1 is on, and the switch SMB2 and the switch SMB3 are off. “0” indicates that the switch SMB2 is on and the switch SMB1 and the switch SMB3 are off. “−VR” indicates that the switch SMB3 is on and the switch SMB1 and the switch SMB2 are off.

The pipeline stage 110a performs the above described operation and outputs an output voltage VQa=VQPa−VQNa of the following expression (2) during the calculation and hold period. The capacitors CM, CFPa, and CFNa have the same capacitance.

$$VQa = 4 \times VIN - VDAC \qquad ( 2 )$$

The voltage VDAC is a result of D/A conversion of the digital value DQa [2:0] by the D/A converter MDACa, and expressed in the following expression (3).

$$DQa [ 2 : 0 ] = 0 \; 00 b : V DAC = 0 , \qquad ( 3 )$$

$$DQa [ 2 : 0 ] = 001 b : V DAC = - V R ,$$

$$DQa [ 2 : 0 ] = 0 \; 10 b : V DAC = - 2 \times V R ,$$

$$DQa [ 2 : 0 ] = 000 b : V DAC = - 3 \times V R ,$$

$$DQa [ 2 : 0 ] = 1 \; 00 b : V DAC = - 4 \times V R ,$$

$$DQa [ 2 : 0 ] = 101 b : V DAC = - 5 \times V R ,$$

$$DQa [ 2 : 0 ] = 1 \; 10 b : V DAC = - 6 \times V R$$

FIG. 10 shows a detailed configuration example of the second pipeline stage. The pipeline stage 110b includes the D/A converter MDACb, a sub-A/D converter 111b, and an encoder 112b.

The positive output voltage VQPa and the negative output voltage VQNa from the pipeline stage 110a are input to the pipeline stage 110b.

The sub-A/D converter 111b performs A/D conversion on the differential voltage (VQPa−VQNa) by the comparison using the reference voltage VR, and outputs the result of the A/D conversion as the digital value DQb [2:0]. The details of the A/D conversion are obtained by replacement of VIN with VQa=VQPa−VQNa and replacement of DQa [2:0] with DQb [2:0] in the above described expression (1).

The encoder 112b encodes the digital value DQb [2:0] to the control signal SWCNT. The details of encoding are the same as those of the encoder 112a of the pipeline stage 110a.

The D/A converter MDACb includes capacitor circuits CSMP1b, CSMP2b, and CSMP3b at the positive side, and capacitor circuits CSMN1b, CSMN2b, and CSMN3b at the negative side. Further, the D/A converter MDACb includes switches SFP1b, SFP2b, SEN1b, SFN2b, SSPb, and SSNb, and capacitors CFPb and CFNb.

The capacitor circuits CSMP1b, CSMP2b, and CSMP3b are provided in parallel between the node of the output voltage VQPa and a node NQPb. The switch SFP1b and the capacitor CFPb are coupled in series between the node of the positive output voltage VQPa from the pipeline stage 110a and the node NQPb. The switch SFP2b is coupled between a node between the switch SFP1b and the capacitor CFPb and a node of a positive output voltage VQPc. The switch SSPb is coupled between the node NQPb and the ground node.

The capacitor circuits CSMN1b, CSMN2b, and CSMN3b are provided in parallel between the node of the output voltage VQNa and a node NQNb. The switch SFN1b and the capacitor CFNb are coupled in series between the node of the positive output voltage VQNa from the pipeline stage 110a and the node NQNb. The switch SFN2b is coupled between a node between the switch SFN1b and the capacitor CENb and a node of a negative output voltage VQNc. The switch SSNb is coupled between the node NQNb and the ground node.

The configuration examples of the respective capacitor circuits CSMP1b, CSMP2b, CSMP3b, CSMN1b, CSMN2b, and CSMN3b are as described in FIG. 7.

FIG. 11 shows a detailed configuration example of the third pipeline stage. The pipeline stage 110c includes the D/A converter MDACc, a sub-A/D converter 111c, and an encoder 112c.

The positive output voltage VQPc and the negative output voltage VQNc are input to the pipeline stage 110c. The pipeline stages 110b and 110c share an operational amplifier OPc and, in the sampling operation of the pipeline stage 110c, the output voltages VQPc and VQNc in the calculation and hold operation of the pipeline stage 110b are input to the pipeline stage 110c.

The sub-A/D converter 111c performs A/D conversion on the differential voltage (VOPc−VQNc) by the comparison using the reference voltage VR, and outputs the result of the A/D conversion as the digital value DQc [2:0]. +VR to −VR corresponds to the full scale of the differential voltage (VQPc−VQNc). The sub-A/D converter 111c performs A/D conversion as in the following expression (4). The difference voltage (VQPc−VQNc) output by the pipeline stage 110b in the calculation and hold operation is denoted by VQb.

$$- V R \leq V Qb \leq - 1 / 4 \times V R : DQc [ 1 : 0 ] = 00 b , \qquad ( 4 )$$

$$- 1 / 4 \times V R < V Qb \leq + 1 / 4 \times V R : DQc [ 1 : 0 ] = 01 b ,$$

$$+ 1 / 4 \times V R < V Qb \leq + V R : DQc [ 1 : 0 ] = 10 b$$

The encoder 112c encodes the digital value DQc [1:0] to the control signal SWCNT. The control of the switch group SMG by the control signal SWCNT will be described later with reference to FIG. 13.

The D/A converter MDACc includes the capacitor circuit CSMPc at the positive side and the capacitor circuit CSMNc at the negative side. The D/A converter MDACc includes switches SFP1c, SFP2c, SFN1c, SEN2c, SSPc, SSNC, SP1c, SP2c, SN1c, and SN2c, capacitors CFPc and CFNc, and the operational amplifier OPc.

The capacitor circuit CSMPc is provided between the node of the output voltage VQPc and a node NQPc. The switch SFP1c and the capacitor CFPc are coupled in series between the node of the output voltage VQPc and the node NQPc. The switch SFP2c is coupled between a node between the switch SFP1c and the capacitor CFPc and the node of the positive output voltage VQPc. The switch SSPc is coupled between the node NQPc and the ground node. The negative output terminal of the operational amplifier OPc is coupled to the node of the positive output voltage VQPc. One end of the switch SP1c is coupled to the node NQPb of the pipeline stage 110b, and the other end is coupled to the positive input terminal of the operational amplifier OPc. One end of the switch SP2c is coupled to the node NQPc, and the other end is coupled to the positive input terminal of the operational amplifier OPc.

The capacitor circuit CSMNc is provided between the node of the output voltage VQNc and a node NQNc. The switch SFN1c and the capacitor CFNc are coupled in series between the node of the output voltage VQNc and the node NQNc. The switch SFN2c is coupled between a node between the switch SENIc and the capacitor CFNc and the node of the negative output voltage VQNc. The switch SSNc is coupled between the node NQNc and the ground node. The positive output terminal of the operational amplifier OPc is coupled to the node of the negative output voltage VQNc. One end of the switch SN1c is coupled to the node NQNb of the pipeline stage 110b, and the other end is coupled to the negative input terminal of the operational amplifier OPc. One end of the switch SN2c is coupled to the node NQNc, and the other end is coupled to the negative input terminal of the operational amplifier OPc.

The configuration examples of the respective capacitor circuits CSMPc and CSMNc are as described in FIG. 7.

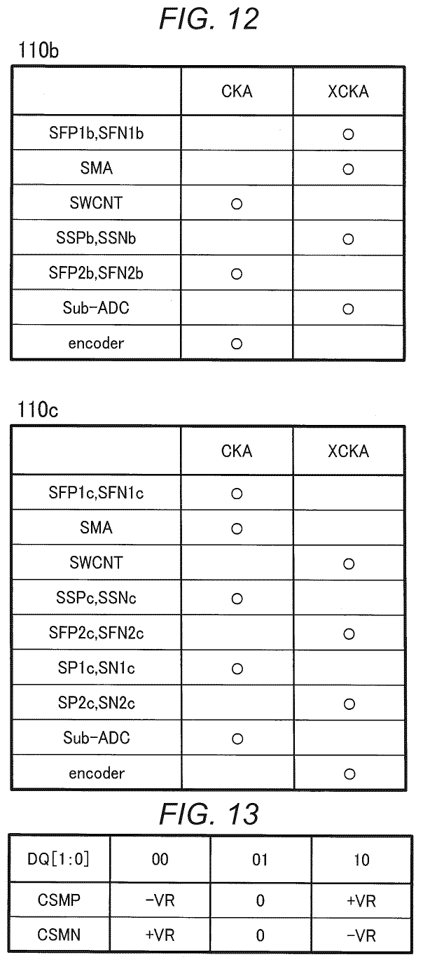

FIG. 12 shows operations of the second and third pipeline stages.

When the clock signal CKA is at the low level, the pipeline stage 110b performs the sampling operation. Specifically, the switches SFP1b, SFN1b, SMA, SSPb, and SSNb of the pipeline stage 110b are on. All of the switches SMB1, SMB2, and SMB3 of the switch group SMG are off. The switches SFP2b and SFN2b are off. The switches SP1c and SN1c of the pipeline stage 110c are off. Thereby, the output voltage VQPa from the pipeline stage 110a is sampled in the capacitors CM of the capacitor circuits CSMP1b, CSMP2b, and CSMP3b and the capacitor CFPb. The output voltage VQNa from the pipeline stage 110a is sampled in the capacitors CM of the capacitor circuits CSMN1b, CSMN2b, and CSMN3b and the capacitor CFNb.

When the clock signal CKA is at the high level, the pipeline stage 110b performs the calculation and hold operation. Specifically, the switches SFP1b, SFN1b, SMA, SSPb, and SSNb are off. The encoder 112b encodes the digital value DQb [2:0] and outputs the control signal SWCNT, and each of the switches SMB1, SMB2, and SMB3 of the switch group SMG is controlled by the control signal SWCNT. The switches SFP2b and SFN2b are on. The switches SP1c and SN1c of the pipeline stage 110c are on. Thereby, a feedback path of the operational amplifier OPc is formed via the capacitors CFPb and CFNb. Here, the operational amplifier OPc functions as an amplifier for the calculation and hold operation of the pipeline stage 110b. The output voltages VQPc and VQNc of the operational amplifier OPc are output voltages in the calculation and hold operation of the pipeline stage 110b.

When the clock signal CKA is at the high level, the pipeline stage 110c performs the sampling operation. Specifically, the switches SFP1c, SEN1c, SMA, SSPc, and SSNc of the pipeline stage 110c are on. All of the switches SMB1, SMB2, and SMB3 of the switch group SMG are off. The switches SFP2c and SFN2c are off. The switches SP2c and SN2c are off. Thereby, the output voltage VQPc in the calculation and hold operation of the pipeline stage 110b is sampled in the capacitor CM of the capacitor circuit CSMPc and the capacitor CFPc. The output voltage VQNc in the calculation and hold operation of the pipeline stage 110b is sampled in the capacitor CM of the capacitor circuit CSMNc and the capacitor CFNc.

When the clock signal CKA is at the low level, the pipeline stage 110c performs the calculation and hold operation. Specifically, the switches SFP1c, SEN1c, SMA, SSPc, and SSNc are off. The encoder 112c encodes the digital value DQc [1:0] and outputs the control signal SWCNT, and each of the switches SMB1, SMB2, and SMB3 of the switch group SMG is controlled by the control signal SWCNT. The switches SFP2c and SFN2c are on. The switches SP2c and SN2c are on. Thereby, a feedback path of the operational amplifier OPc is formed via the capacitors CFPc and CFNc. Here, the operational amplifier OPc functions as an amplifier for the calculation and hold operation of the pipeline stage 110c. The output voltages VQPc and VON of the operational amplifier OPc are output voltages in the calculation and hold operation of the pipeline stage 110c.

FIG. 13 shows operations of an encoder and a switch group in a calculation and hold operation of a 1.5-bit pipeline stage. In FIG. 13, the column of “DQ [1:0]” indicates the respective values of the digital value DQc [1:0]. The row of “CSMP” indicates the operation of the switch group SMG of the capacitor circuit CSMPc in the respective values of the digital value DQc [1:0]. The same applies to the row of “CSMN”. The meanings of “+VR”, “0”, and “−VR” are as described in FIG. 9.

The pipeline stage 110b performs the above described operation and outputs the output voltage VOb=VQPc-VQNc of the following expression (5) during the calculation and hold period. The capacitors CM, CFPb, and CFNb have the same capacitance. The voltage VDAC is obtained by replacement of DQa [2:0] with DQb [2:0] in the above described expression (3).

$$V Qb = 4 \times V Qa - V DAC \qquad ( 5 )$$

The pipeline stage 110c performs the above described operation and outputs an output voltage VQc=VQPc−VQNc of the following expression (6) during the calculation and hold period. The capacitors CM, CFPc, and CFNc have the same capacitance.

$$V Qc = 2 \times V Qb - V DAC \qquad ( 6 )$$

The voltage VDAC is a result of D/A conversion of the digital value DQc [1:0] by the D/A converter MDACc, and expressed by the following expression (7).

$$DQc [ 1 : 0 ] = 00 b : V DAC = 0 , \qquad ( 7 )$$

$$DQc [ 1 : 0 ] = 01 b : V DAC = - V R ,$$

$$DQc [ 1 : 0 ] = 10 b : V DAC = - 2 \times V R$$

In the above description, the example in which the pipeline stages 110b and 110c share the amplifier is shown, however, each of the pipeline stages 110b and 110c may be provided with an operational amplifier.

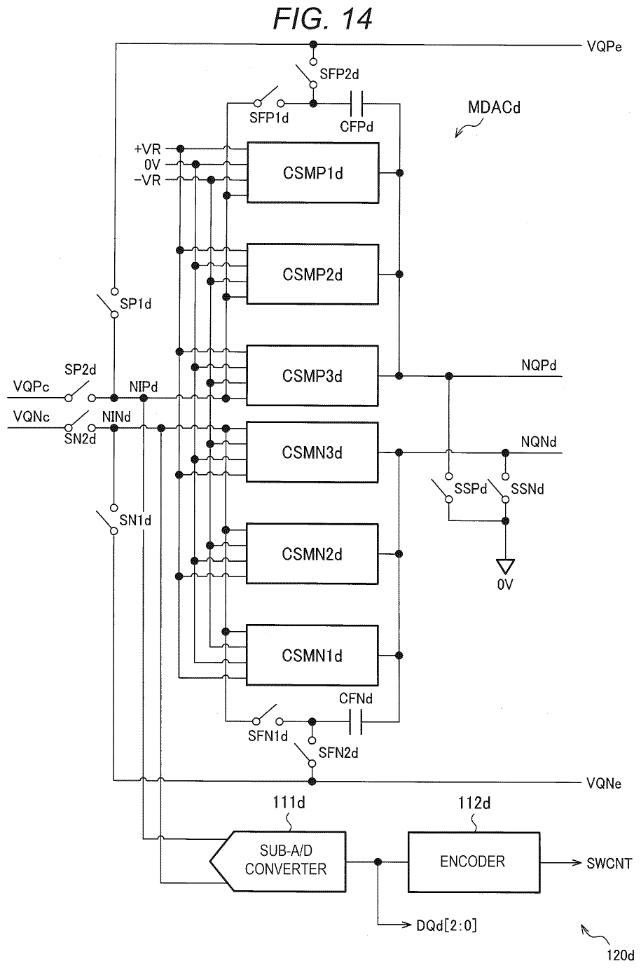

FIG. 14 shows a detailed configuration example of the first stage of the cyclic A/D converter. The first stage 120d includes a D/A converter MDACd, a sub-A/D converter 111d, an encoder 112d, and switches SP1d, SP2d, SN1d, and SN2d.

The positive output voltage VQPc and the negative output voltage VQNc of the pipeline stage 110c are input to the first stage 120d.

One end of the switch SP2d is coupled to the node of the output voltage VQPc from the pipeline stage 110c, and the other end is coupled to a node NIPd. One end of the switch SP1d is coupled to a node of an output voltage VQPe from an operational amplifier OPe of the second stage 120e, and the other end is coupled to the node NIPd. One end of the switch SN2d is coupled to the node of the output voltage VQNc from the pipeline stage 110c, and the other end is coupled to a node NINd. One end of the switch SN1d is coupled to a node of an output voltage VQNe from the operational amplifier OPe of the second stage 120e, and the other end is coupled to the node NINd.

The differential voltage between the nodes NIPd and NINd is denoted by VNId. The sub-A/D converter 111d performs A/D conversion on the differential voltage VNId by the comparison using the reference voltage VR, and outputs the result of the A/D conversion as the digital value Dod [2:0]. The details of the A/D conversion are obtained by replacement of VIN with VNId and replacement of DQa [2:0] with DQd [2:0] in the above described expression (1).

The encoder 112d encodes the digital value DQd [2:0] to the control signal SWCNT. The details of encoding are the same as those of the encoder 112a of the pipeline stage 110a.

The D/A converter MDACd includes capacitor circuits CSMP1d, CSMP2d, and CSMP3d at the positive side, and capacitor circuits CSMN1d, CSMN2d, and CSMN3d at the negative side. The D/A converter MDACd includes switches SFP1d, SFP2d, SFN1d, SFN2d, SSPd and SSNd, and capacitors CFPd and CFNd.

The capacitor circuits CSMP1d, CSMP2d, and CSMP3d are provided in parallel between the node NIPd and a node NQPd. The switch SFP1d and the capacitor CFPd are coupled in series between the node NIPd and the node NQPd. The switch SFP2d is coupled between a node between the switch SFP1d and the capacitor CFPd and the node of the positive output voltage VQPe. The switch SSPd is coupled between the node NQPd and the ground node.

The capacitor circuits CSMN1d, CSMN2d, and CSMN3d are provided in parallel between the node NINd and a node NQNd. The switch SFN1d and the capacitor CFNd are coupled in series between the node NINd and the node NQNd. The switch SFN2d is coupled between a node between the switch SFN1d and the capacitor CFNd and the node of the negative output voltage VQNe. The switch SSNd is coupled between the node NQNd and the ground node.

The configuration examples of the capacitor circuits CSMP1d, CSMP2d, CSMP3d, CSMN1d, CSMN2d, and CSMN3d are as described in FIG. 7.

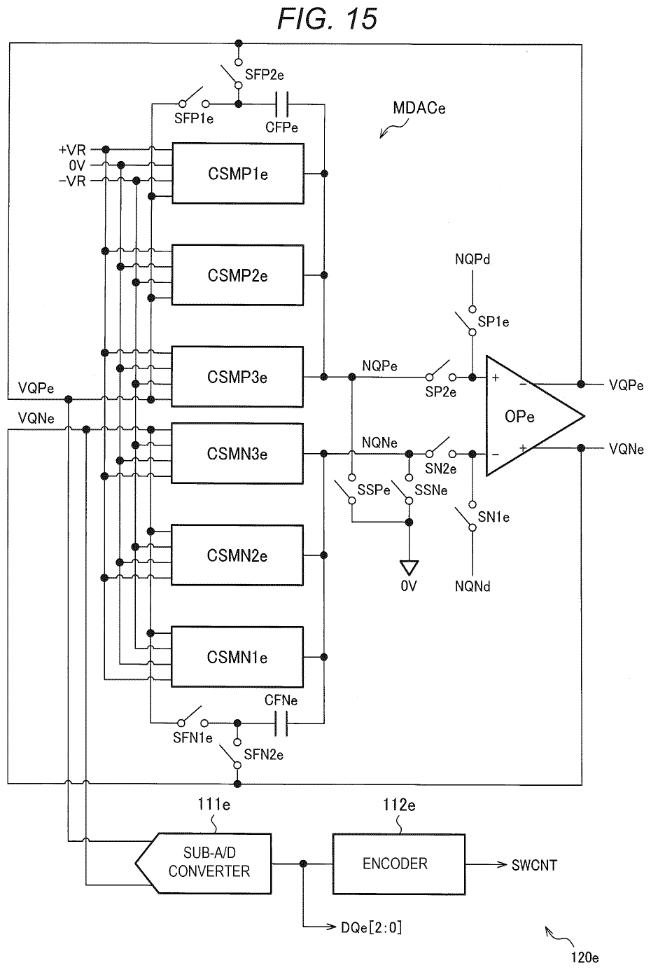

FIG. 15 shows a detailed configuration example of the second stage of the cyclic A/D converter. The second stage 120e includes a D/A converter MDACe, a sub-A/D converter 111e, and an encoder 112e.

The positive output voltage VQPe and the negative output voltage VQNe are input to the second stage 120e. The first stage 120d and the second stage 120e share the operational amplifier OPe and, in the sampling operation of the second stage 120e, the output voltages VQPe and VQNe in the calculation and hold operation of the first stage 120d are input to the second stage 120e.

The sub-A/D converter 111e performs A/D conversion on the differential voltage (VQPe-VQNe) by the comparison using the reference voltage VR, and outputs the result of the A/D conversion as the digital value DQe [2:0]. The differential voltage (VQPe-VQNe) output by the first stage 120d in the calculation and hold operation is denoted by VQd. The details of the A/D conversion performed by the sub-A/D converter 111e are obtained by replacement of VIN with VQd and replacement of DQa [2:0] with DQe [2:0] in the above described expression (1).

The encoder 112e encodes the digital value DQe [2:0] to the control signal SWCNT. The details of encoding are the same as those of the encoder 112a of the pipeline stage 110a.

The D/A converter MDACe includes capacitor circuits CSMP1e, CSMP2e, and CSMP3e at the positive side, and capacitor circuits CSMN1e, CSMN2e, and CSMN3e at the negative side. The D/A converter MDACe includes switches SFP1e, SFP2e, SEN1e, SFN2e, SSPe, SSNe, SP1e, SP2e, SN1e, and SN2e, capacitors CFPe and CFNe, and the operational amplifier OPe.

The capacitor circuits CSMP1e, CSMP2e, and CSMP3e are provided in parallel between the node of the output voltage VQPe and a node NQPe. The switch SFP1e and the capacitor CFPe are coupled in series between the node of the output voltage VQPe and the node NQPe. The switch SFP2e is coupled between a node between the switch SFP1e and the capacitor CFPe and the node of the positive output voltage VQPe. The switch SSPe is coupled between the node NQPe and the ground node. The negative output terminal of the operational amplifier OPe is coupled to the node of the positive output voltage VQPe. One end of the switch SP1e is coupled to the node NQPd of the first stage 120d, and the other end is coupled to the positive input terminal of the operational amplifier Ope. One end of the switch SP2e is coupled to the node NQPe, and the other end is coupled to the positive input terminal of the operational amplifier OPe.

The capacitor circuits CSMN1e, CSMN2e, and CSMN3e are provided in parallel between the node of the output voltage VQNe and a node NQNe. The switch SFNe and the capacitor CFNe are coupled in series between the node of the output voltage VQNe and the node NQNe. The switch SFN2e is coupled between a node between the switch SFN1e and the capacitor CFNe and the node of the negative output voltage VQNe. The switch SSNe is coupled between the node NQNe and the ground node. The positive output terminal of the operational amplifier OPe is coupled to the node of the negative output voltage VQNe. One end of the switch SN1e is coupled to the node NQNd of the first stage 120d, and the other end is coupled to the negative input terminal of the operational amplifier OPe. One end of the switch SN2e is coupled to the node NQNe, and the other end is coupled to the negative input terminal of the operational amplifier Ope.

The configuration examples of the capacitor circuits CSMP1e, CSMP2e, CSMP3e, CSMN1e, CSMN2e, and CSMN3e are as described in FIG. 7.

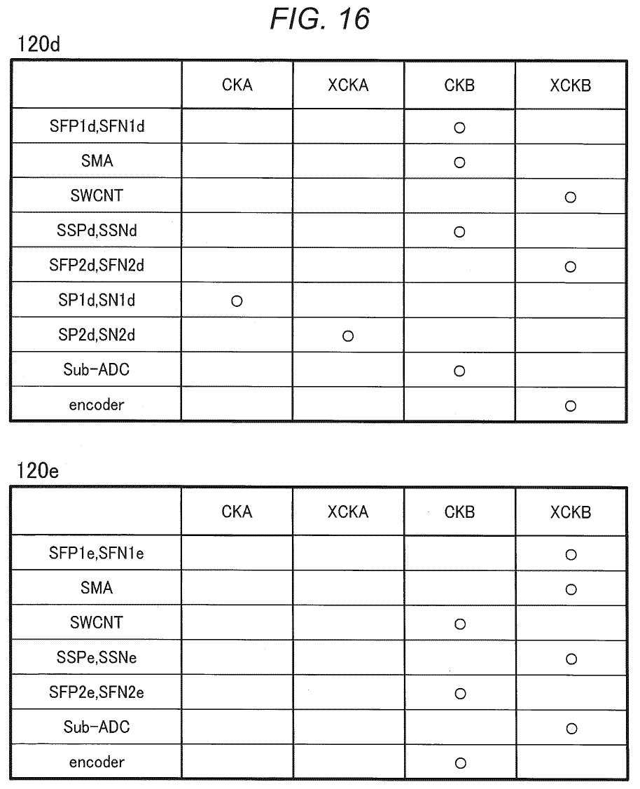

FIG. 16 shows operations of the first stage and the second stage of the cyclic A/D converter.

When the clock signal CKA is at the low level, the switches SP1d and SN1d are off, the switches SP2d and SN2d are on, and the pipeline stage 110c performs the calculation and hold operation. The voltages at the nodes NIPd and NINd of the first stage 120d are the output voltages VQPc and VQNc in the calculation and hold operation of the pipeline stage 110c. That is, when the clock signal CKA is at the low level, the cyclic A/D converter 120 performs the first-cycle A/D conversion with the output voltages VQPc and VQNc in the calculation and hold operation of the pipeline stage 110c as input.

When the clock signal CKA is at the high level, the switches SP1d and SN1d are on, and the switches SP2d and SN2d are off. The voltages at the nodes NIPd and NINd of the first stage 120d are the output voltages VQPe and VQNe by the first-cycle A/D conversion of the cyclic A/D converter 120. That is, when the clock signal CKA is at the high level, the cyclic A/D converter 120 performs the second-cycle A/D conversion with the output voltages VQPe and VQNe by the first-cycle A/D conversion of the cyclic A/D converter 120 as input.

When the clock signal CKB is at the high level, the first stage 120d performs the sampling operation, and the second stage 120e performs the calculation and hold operation. When the clock signal CKB is at the low level, the first stage 120d performs the calculation and hold operation, and the second stage 120e performs the sampling operation. The operations of the first stage 120d and the second stage 120e here are the same as the operations of the pipeline stages 110b and 110c. Note that the first stage 120d and the second stage 120e use the clock signal CKB as the operation clock, and operate in a half of the operation cycle of the pipeline stages 110b and 110c.

In the above description, the example in which the first stage 120d and the second stage 120e of the cyclic A/D converter 120 share the amplifier is shown, however, each of the first stage 120d and the second stage 120e may be provided with an operational amplifier.

In the above described configuration, a case where the first stage 120d of the cyclic A/D converter 120 samples the output voltage of the pipeline stage 110c is considered. The pipeline stage 110c of FIG. 11 performs the calculation and hold operation, and a feedback path of the operational amplifier OPc is formed via the capacitors CFPc and CFNc. The capacitor circuits CSMPc and CSMNc are loads on the feedback path. In this state, the switches SP2d and SN2d are turned on in the first stage 120d of the cyclic A/D converter 120 of FIG. 14, and sampling is started. The operational amplifier OPc of the pipeline stage 110c charges the capacitor circuit CMP1d and the like of the first stage 120d, and thereby, the sampled voltage is settled.

Here, since the number of bits of the pipeline stage 110c is smaller, the number of capacitor circuits of the pipeline stage 110c is smaller, and the load appearing in the feedback path of the operational amplifier OPc is smaller. Accordingly, the operational amplifier OPc can settle the sampled voltage of the first stage 120d faster, and accurate sampling can be performed even when the sampling period of the first stage 120d is shorter.

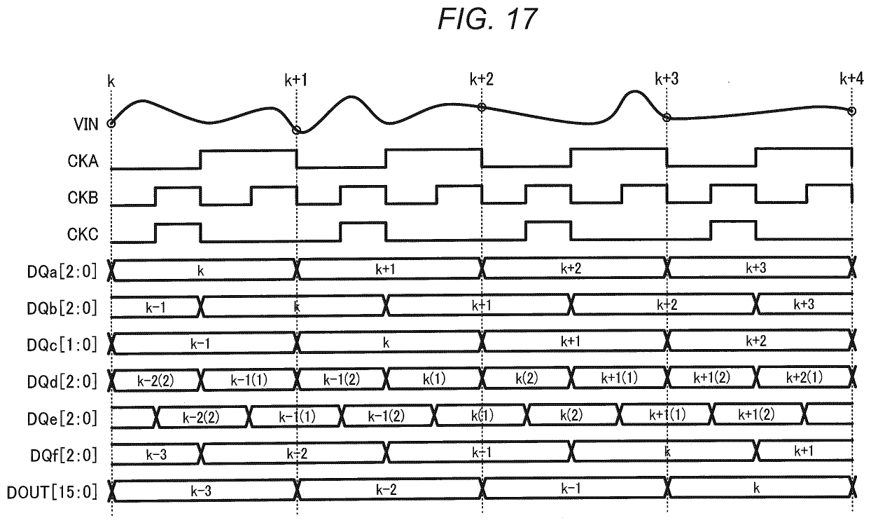

FIG. 17 shows a timing chart example illustrating an overall operation of the A/D converter circuit shown in FIG. 1.

The vertical dotted lines indicate timing at which the first pipeline stage 110a determines a sampling value. The circles attached to the intersections of the vertical dotted lines and the waveform of the input voltage VIN indicate the determined sampling values. The pipeline stage 110a performs sampling in a period in which the clock signal CKA is at the high level, and determines the sampling value at the trailing edge of the clock signal CKA.

The sampling value is determined in time series at each trailing edge of the clock signal CKA. The numbers “k”, “k+1”, “k+2”, . . . are assigned to the time-series sampling values. The numbers are similarly assigned to the waveforms of the respective digital values, and indicate the correspondences between the sampling values and the digital values.

In the waveforms of the digital values DQd [2:0] and DQe [2:0] as the output of the cyclic A/D converter 120, “(1)” indicates the result of the first-cycle A/D conversion, and “(2)” indicates the result of the second-cycle A/D conversion.

The sub-A/D converter of each stage updates the digital value at the end of the sampling period of each stage. For example, the pipeline stage 110a performs sampling in a period in which the clock signal CKA is at the high level, and the sub-A/D converter 111a updates the digital value DQa [2:0] at the trailing edge of the clock signal CKA. Further, for example, the pipeline stage 110b performs sampling in a period in which the clock signal CKA is at the low level, and the sub-A/D converter 111a updates the digital value DQa [2:0] at the rising edge of the clock signal CKA. The flash A/D converter 130 updates the digital value DQf [2:0] at the trailing edge of the clock signal CKC.

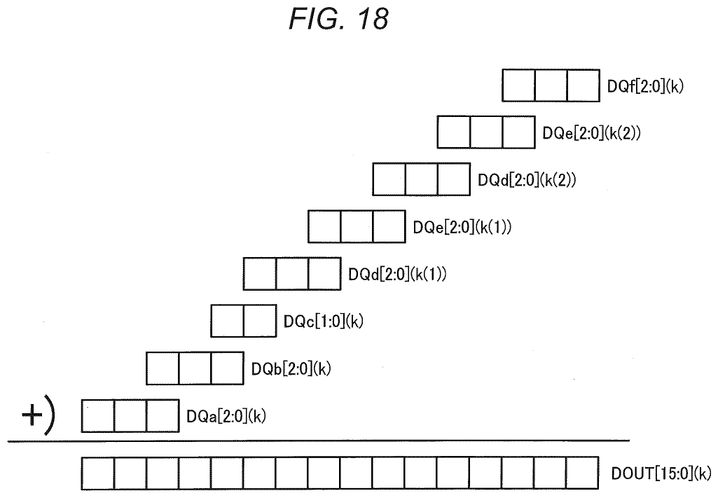

FIG. 18 shows an operation of the adder. One square corresponds to one bit of a digital value. The left direction in the drawing is the higher bit side. (k) indicates a digital value corresponding to the k-th sampling value. (k(1)) indicates a digital value corresponding to the k-th sampling value and a result of the first-cycle A/D conversion of the cyclic A/D converter 120. (k(2)) indicates a digital value corresponding to the k-th sampling value and a result of the second-cycle A/D conversion of the cyclic A/D converter 120.

The adder 190 performs addition processing shown in FIG. 18 to obtain the output digital value DOUT [15:0] of the A/D converter circuit 100 from the digital values of the respective stages. Specifically, the adder 190 arranges DQf [0] (k), DQf [1] (k), and DQf [2] (k) from the LSB to the first digit, the second digit, and the third digit, respectively, arranges DQe [0] (k(2)), DQe [1 (k(2)), and DQe [2] (k(2)) from the LSB to the third digit, the fourth digit, and the fifth digit, respectively, subsequently arranges the respective digital values in the similar manner, and then, adds the digital values arranged side by side.

Although the embodiments are described in detail as above, those skilled in the art could easily understand that many modifications can be made without substantially departing from the novel matters and the effects of the present disclosure. Accordingly, all the modifications are within the scope of the present disclosure. For example, a term described at least once together with a different term having a broader meaning or the same meaning in the specification or the drawings can be replaced with the different term at any place in the specification or the drawings. All combinations of the embodiments and the modifications are also within the scope of the present disclosure. The configurations, operations, etc. of the pipeline stage, the cyclic A/D converter, the flash A/D converter, the successive approximation A/D converter, the adder, the A/D converter circuit, and the like are not limited to those described in the embodiment, and various modifications can be made.

What is claimed is:

1. An A/D converter circuit comprising:
a first pipeline stage outputting a first digital value of x bits by A/D conversion based on an input signal;
a second pipeline stage outputting a second digital value of y bits smaller than the x bits by A/D conversion based on a first analog output signal of the first pipeline stage; and
an A/D converter sampling a second analog output signal of the second pipeline stage in a sampling period shorter than a sampling period of the first pipeline stage and a sampling period of the second pipeline stage, performing A/D conversion based on a sampling result, and outputting a third digital value.

2. The A/D converter circuit according to claim 1, wherein
the first pipeline stage performs a sampling operation in a first period,
in a second period after the first period, the first pipeline stage performs a calculation and hold operation and the second pipeline stage performs a sampling operation, and
in a third period after the second period, the second pipeline stage performs a calculation and hold operation and the A/D converter performs a sampling operation.

3. The A/D converter circuit according to claim 1, wherein
the A/D converter is a cyclic A/D converter.

4. The A/D converter circuit according to claim 3, wherein
the cyclic A/D converter performs a first-cycle A/D conversion of A/D-converting the second analog output signal and a second-cycle A/D conversion of A/D-converting an analog output signal output by the first-cycle A/D conversion from the cyclic A/D converter again in a period in which the first pipeline stage and the second pipeline stage perform single A/D conversion.

5. The A/D converter circuit according to claim 1, wherein
the A/D converter is a successive approximation A/D converter.

6. The A/D converter circuit according to claim 5, wherein
the successive approximation A/D converter performs a sampling operation of sampling the second analog output signal and a successive approximation operation on the sampled second analog output signal in a period in which the first pipeline stage and the second pipeline stage perform single A/D conversion.

7. The A/D converter circuit according to claim 1, wherein
the x bits are n+0.5 bits, n being an integer of one or more, and the y bits are m+0.5 bits, m being an integer of one or more and less than n.

8. The A/D converter circuit according to claim 1, wherein
the third digital value is of z bits larger than the x bits and the y bits.

9. The A/D converter circuit according to claim 1, further comprising a flash A/D converter provided downstream of the A/D converter.

10. The A/D converter circuit according to claim 1, further comprising an adder outputting an output digital value of the A/D converter circuit based on the first digital value, the second digital value, and the third digital value.
